(19) United States
(12) Patent Application Publication
(10) Pub. No.: US 2021/0302841 A1
(43) Pub. Date: Sep. 30, 2021

(54) SUBSTRATE PROCESSING METHOD AND SUBSTRATE PROCESSING APPARATUS

(71) Applicant: SCREEN HOLDINGS CO., LTD., Kyoto (JP)

(72) Inventors: Akira Horikoshi, Kyoto (JP); Shohei Nakamura, Kyoto (JP); Shigeru Takatsuji, Kyoto (JP); Takahiro Kimura, Kyoto (JP)

(21) Appl. No.: 17/200,141

(22) Filed: Mar. 12, 2021

(30) Foreign Application Priority Data
Mar. 24, 2020 (JP) 2020-052761

(51) Int. Cl. G03F 7/36; H01L 21/02; H01J 37/32

(52) U.S. Cl. CPC G03F 7/36; H01L 21/02057; H01J 2237/327; H01J 37/3244; H01J 37/32715

(57) ABSTRACT

The radical supply step of supplying the radicals (active species) to the resist film R is performed in the plasma processing (Step S102). Then, the resist removal step of supplying the organic solvent having the low surface tension to the resist film R present on the front surface Sa of the substrate S after the radical supply step to remove the resist film R from the front surface Sa of the substrate S is performed (Step S104).

### CROSS REFERENCE TO RELATED APPLICATION

The disclosure of Japanese Patent Application No.2020-052761 filed on Mar. 24, 2020 including specification, drawings and claims is incorporated herein by reference in its entirety.

### BACKGROUND OF THE INVENTION

### 1. Field of the Invention

This invention relates to a technique for performing a process to a substrate using a plasma and particularly to a technique for removing a resist film from a semiconductor substrate made of silicon or the like.

### 2. Description of the Related Art

Conventionally, a plasma ashing technique is one of methods for removing a resist film formed on a surface of a substrate. Plasma ashing is a technique for breaking carbon-hydrogen bonds in a resist film to remove the resist film or set the resist film in an easily removable state by causing ionic molecules and the like produced by a plasma to collide with the resist film formed on a substrate. In plasma ashing, a plasma generation space for generating a plasma is typically formed in a vacuum chamber and a plasma is generated in the plasma generation space to increase a gas energy in the plasma generation space. In this way, various active species are produced. To transfer the active species to the substrate, ionic molecules (typically cationic molecules) included in the active species transfer toward the substrate and collide with the substrate by adjusting a potential distribution between the plasma generation space and the substrate. By this collision, carbon-hydrogen bonds of the resist film on the substrate are broken. Plasma ashing method and apparatus are described, for example, in JP H07-37314B.

### SUMMARY OF THE INVENTION

In plasma ashing, carbon bonds of the resist film can be efficiently broken by the collision of the active species mainly including cations with the resist film. On the other hand, there is a problem that cations having a high energy damage is the substrate.

A method for supplying a mixture liquid of H₂SO₄/H₂O₂/H₂O (Sulfuric acid/hydrogen Peroxide/water Mixture; hereinafter, abbreviated as “SPM”) to a resist film on a substrate and dissolving and removing a resist film by the SPM is known as another method for removing a resist film on a substrate. The reuse of the SPM is difficult and it has been a problem in recent years to decrease the consumption of the SPM.

This invention was developed in view of the above problem and aims to provide a technique suppressing damage on a substrate in removing a resist film using a plasma and not requiring the use of SPM.

A substrate processing method according to the invention, comprises: a plasma generation step of generating a plasma under an atmospheric pressure; a radical production step of producing radicals by the plasma generated in the plasma generation step; a radical supply step of supplying the radicals to a resist film formed on a front surface of a substrate and deteriorating the vicinity of a front surface of the resist film while keeping the resist film in contact with the front surface of the substrate; a resist removal step of removing the resist film from the front surface of the substrate by supplying an organic solvent having a low surface tension to the resist film on the front surface of the substrate after the radical supply step; and a rinsing step of supplying a rinsing liquid to the front surface of the substrate after the resist removal step.

In the invention (substrate processing method) thus configured, the radical supply step of supplying the radicals to the resist film and the resist removal step of removing the resist film from the front surface of the substrate by supplying the organic solvent having the low surface tension to the resist film on the front surface of the substrate after the radical supply step are performed. When a plasma is generated under an atmospheric pressure, most of ionic molecules, out of active species produced react with molecules in the atmosphere and disappear in a moment. Out of the remaining active species, electrically neutral free radicals are supplied to the resist film. Most of the ionic molecules, which are a main cause to damage the substrate, are not supplied to the resist film. Further, when the radical supply step is finished, the resist film is present on the front surface of the substrate and not removed yet. Thus, damage on the substrate is suppressed. The radicals having reached the front surface of the resist film penetrate into the front surface of the resist film to deteriorate the vicinity of the front surface of the resist film. As a result, fine cracks and holes are formed near the front surface of the resist film. Subsequently, when the organic solvent is supplied, the organic solvent penetrates into these cracks and holes to expand these cracks and holes. In this way, a chemical action, i.e. deterioration by the active species and a physical action, i.e. expansion of the holes and cracks by the organic solvent having the low surface tension are coupled, and the removal of the resist film is accomplished. In this way, it is possible to suppress damage on the substrate in removing the resist film using a plasma and eliminate need for the use of SPM.

A substrate processing apparatus which removes a resist film on a substrate according to the invention, comprises: a holder which horizontally holds the substrate under an atmospheric pressure; a plasma generator which includes an active species nozzle and an electrode arranged inside the active species nozzle and supplies active species activated by a plasma generated by applying a voltage to the electrode by the active species nozzle; and an organic solvent nozzle which supplies an organic solvent having a low surface tension, wherein a distance from the electrode inside the active species nozzle to a front surface of the resist film on the substrate held by the holder is set at such a distance that hydroxyl radicals included in the active species reach the front surface of the resist film from the electrode within the lives of the hydroxyl radicals.

According to the inventor's research, the deterioration of a front surface of a resist film on a substrate under an atmospheric pressure is thought to be largely affected by the action of hydroxyl radicals. Accordingly, in the substrate processing apparatus according to the invention, the distance from the electrode in the active species nozzle to the resist film on the substrate held by the holder is set at such a distance that the hydroxyl radicals included in the active species reach the front surface of the resist film from the electrode within the lives of the hydroxyl radicals. In this way, the front surface of the resist film can be efficiently deteriorated.

As described above, according to the invention, it is possible to suppress damage on a substrate and eliminate need for the use of SPM in removing a resist film using a plasma.

As described above, according to the invention, the formation of wrinkles in an ink discharge range can be suppressed in printing an image by discharging ink to a printing medium while conveying the printing medium in a conveying direction.

### BRIEF DESCRIPTION OF THE DRAWINGS

FIG. 1 is a flow chart showing an example of a substrate processing method according to the invention.

FIG. 2 is a chart schematically showing an operation performed in FIG. 1.

FIG. 3 is a diagram schematically showing an example of a plasma processing apparatus used in the substrate processing method of FIG. 1.

FIG. 4 is a diagram schematically showing an example of a processing liquid supply apparatus used in the substrate processing method of FIG. 1.

FIG. 5 is a diagram schematically showing a modification of the plasma processing apparatus.

FIG. 6A is a partial sectional view schematically showing a plasma generator equipped in the plasma processing apparatus of FIG. 5.

FIG. 6B is a partial perspective view schematically showing the plasma generator equipped in the plasma processing apparatus of FIG. 5.

FIG. 7 is a diagram schematically showing an example of a substrate processing apparatus according to the invention.

### DETAILED DESCRIPTION OF THE PREFERRED EMBODIMENTS

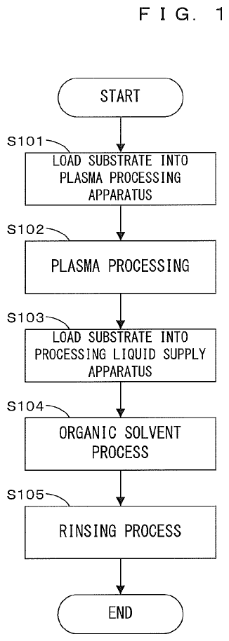

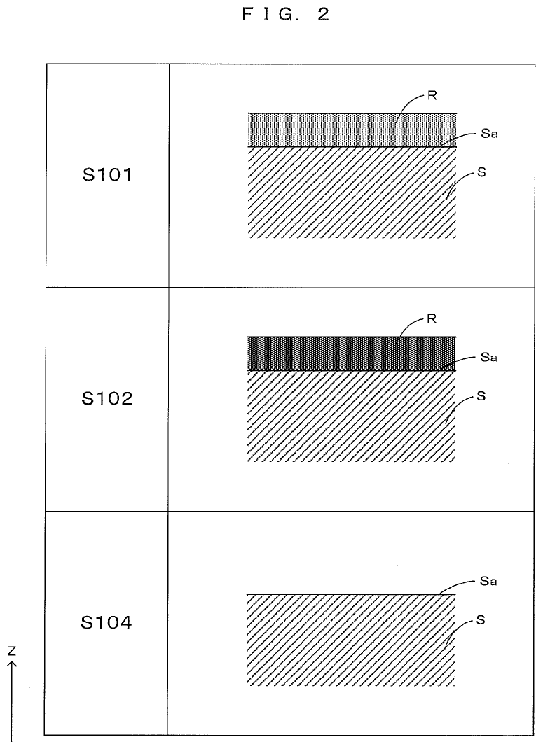

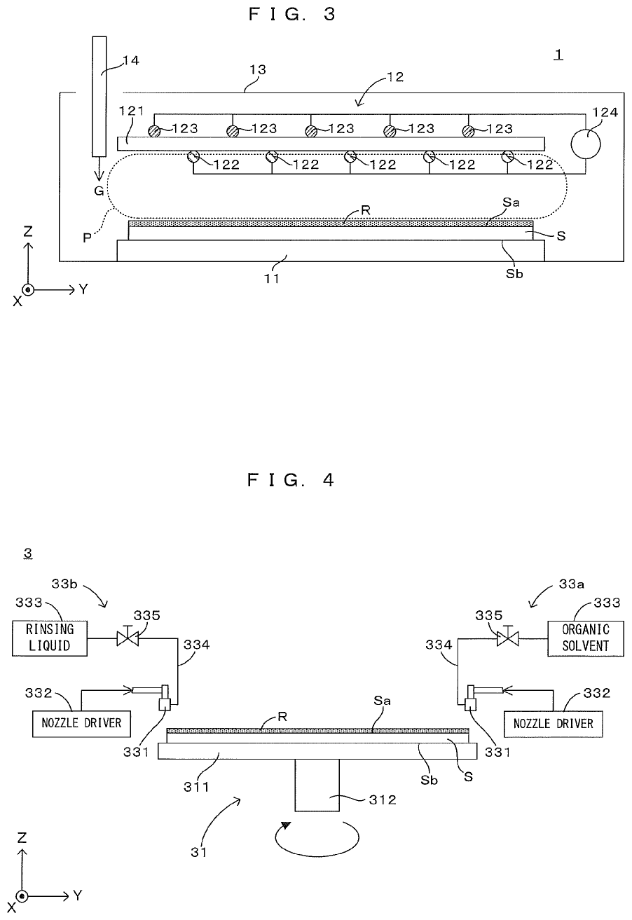

FIG. 1 is a flow chart showing an example of a substrate processing method according to the invention, FIG. 2 is a chart schematically showing an operation performed in FIG. 1, FIG. 3 is a diagram schematically showing an example of a plasma processing apparatus used in the substrate processing method of FIG. 1, and FIG. 4 is a diagram schematically showing an example of a processing liquid supply apparatus used in the substrate processing method of FIG. 1. An X direction, which is a horizontal direction, and a Y direction, which is a horizontal direction orthogonal to the X direction, or a Z direction, which is a vertical direction, are shown as appropriate in FIGS. 2 to 4.

In Step S101, a substrate S is loaded into a plasma processing apparatus 1. The substrate S has a front surface Sa and a back surface Sb opposite to the front surface Sa, and a resist film R is formed on the front surface Sa of the substrate S (FIGS. 2 and 3). Particularly, ions are implanted into a surface layer of the resist film R by ion implantation previously performed to the substrate S, whereby the surface layer of the resist film R is hardened. As shown in FIG. 3, the plasma processing apparatus 1 includes a holding table 11 for holding the loaded-in substrate S, and the holding table 11 horizontally holds the substrate S with the front surface Sa facing upward.

Further, the plasma processing apparatus 1 includes a plasma generator 12 above the holding table 11, and the plasma generator 12 is facing the resist film R on the front surface Sa of the substrate S held on the holding table 11 from above. The plasma generator 12 includes a separation plate 121 having a flat plate shape and made of a dielectric such as quartz glass, and the lower surface of this separation plate 121 is facing the resist film R from above.

The plasma generator 12 includes electrodes 122 arranged on the lower surface of this separation plate 121 and electrodes 123 arranged on the upper surface of the separation plate 121. The electrodes 122, 123 extend in the X direction. A plurality of the electrodes 122 are arrayed in the Y direction on the lower surface of the separation plate 121, and a plurality of the electrodes 123 are arrayed in the Y direction on the upper surface of the separation plate 121. These electrodes 122, 123 are arranged in a staggered manner, in other words, the electrodes 122, 123 are alternately arranged in a plan view in the Z direction. Further, the plasma generator 12 includes an alternating-current power source 124, and this alternating-current power source 124 applies an alternating-current voltage between the electrodes 122 and 123.

Further, the plasma processing apparatus 1 includes a housing 13 which houses the holding table 11 and the plasma generator 12, and a gas supply pipe 14 which supplies a gas G into the housing 13. The gas G is, for example, an argon gas, a nitrogen gas or the like.

In a plasma processing of Step S102, the plasma generator 12 generates a plasma. That is, the gas G is supplied to around the separation plate 121 from the gas supply pipe 14. Thus, the gas G around the separation plate 121 is plasmatized by the alternating-current voltage applied between the electrodes 122 and 123 to generate a plasma P (plasma generation step). Further, the plasma P is generated at an atmospheric pressure, and oxygen exists around the plasma generator 12. Accordingly, oxygen is activated by the plasma P and active species including hydroxyl radicals and the like are produced (radical production step). Some of the radicals produced in this way are supplied to the resist film R and act with the front surface of the resist film R (radical supply step). Note that if a plasma is generated under an atmospheric pressure, most of ionic molecules, out of the produced active species, react with molecules in the atmosphere and disappear in a moment. Out of the remaining active species, still living ones of electrically neutral free radicals are supplied to the resist film. Free radicals produced by a plasma include superoxide anion radicals, hydroxy radicals and the like.

In FIG. 2, the vicinity of the front surface Sa of the substrate S after the substrate S is loaded into the plasma processing apparatus 1 and before the plasma processing is performed is shown in a field of “S101”, and the vicinity of the front surface Sa of the substrate S after the plasma processing is performed is shown in a field of “S102”. As schematically shown in these fields, the resist film R is present on the front surface Sa of the substrate S even if the plasma processing is performed.

The substrate S having the plasma processing performed therefor is unloaded from the plasma processing apparatus 1 and loaded into a processing liquid supply apparatus 3 (Step S103). As shown in FIG. 4, the processing liquid supply apparatus 3 includes a substrate holder 31 which holds the substrate S. The substrate holder 31 includes a holding plate 311 which horizontally holds the substrate S and a rotary shaft 312 which rotates together with the holding plate 311 about a center axis parallel to the Z direction. The holding plate 311 holds the substrate S arranged on the upper surface thereof by chuck pins or vacuum. Thus, the substrate S held on the holding plate 311 rotates together with the rotary shaft 312.

Further, the processing liquid supply apparatus 3 includes processing liquid supply mechanisms 33a, 33b which supplies a processing liquid to the front surface Sa of the substrate S held by the substrate holder 31. The processing liquid supply mechanisms 33a, 33b have a common configuration although differing in the kind of the processing liquid to be supplied. Accordingly, the processing liquid supply mechanism 33a is described and the processing liquid supply mechanism 33b is denoted by corresponding reference signs and not described.

The processing liquid supply mechanism 33a includes a nozzle 331 movable in the Y direction, a nozzle driver 332 which drives the nozzle 331 in the Y direction, a storage container 333 which stores the processing liquid, a pipe 334 connecting the storage container 333 and the nozzle 331 and a valve 335 provided in the pipe 334. An organic solvent having a low surface tension is stored in the storage container 333 of the processing liquid supply mechanism 33a. Here, the organic solvent having the low surface tension has a lower surface tension than at least a sulfuric acid and is, for example, ethanol, isopropyl alcohol, acetone or the like. If the valve 335 is opened, the storage container 333 and the nozzle 331 communicate and the organic solvent is supplied from the storage container 333 to the nozzle 331. In this way, the organic solvent is discharged from the nozzle 331.

Further, a rinsing liquid is stored in the storage container 333 in the processing liquid supply mechanism 33b. Accordingly, if the valve 335 is opened, the rinsing liquid is supplied from the storage container 333 to the nozzle 331 and discharged from the nozzle 331. Here, the rinsing liquid is a liquid different from the liquid supplied in the processing liquid supply mechanism 33a and is, for example, pure water (deionized water), carbonated water, electrolyzed ionized water, hydrogen water, ozone water or the like.

In Step S104, the processing liquid supply mechanism 33a drives the nozzle 331 above the substrate S in the Y direction by the nozzle driver 332 and discharges the organic solvent from the nozzle 331 while the substrate holder 31 is rotating the substrate S. In this way, the organic solvent is supplied to the entire resist film R of the substrate S, and the resist film R is removed from the front surface Sa of the substrate S as shown in a field of “Step S104” of FIG. 2 (resist removal step). In Step S105, the processing liquid supply mechanism 33b drives the nozzle 331 above the substrate S in the Y direction by the nozzle driver 332 and discharges the rinsing liquid from the nozzle 331 while the substrate holder 31 is rotating the substrate S. In this way, the rinsing liquid is supplied to the entire front surface Sa of the substrate S from which the resist film R has been removed (rinsing step). Then, the substrate processing method of FIG. 1 is finished.

In the embodiment described above, the radical supply step of supplying the radicals (active species) to the resist film R is performed in the plasma processing (Step S102). Then, the resist removal step of supplying the organic solvent having the low surface tension to the resist film R present on the front surface Sa of the substrate S after the radical supply step to remove the resist film R from the front surface Sa of the substrate S is performed (Step S104). That is, when the supply of the radicals to the resist film R by the radical supply step is finished, the resist film R is present on the front surface Sa of the substrate S and not removed yet. Thus, damage on the substrate S is suppressed. However, the resist film R is not removed, but is deteriorated in the vicinity of the front surface by the supply of the radicals. Such a resist film R can be quickly removed by supplying the organic solvent having the low surface tension. In this way, it is possible to eliminate need for the use of SPM while suppressing damage on the substrate S in removing the resist film R using the plasma P.

A mechanism capable of removing the resist film R in this way is presumed as follows. The radicals supplied to the resist film R in the radical supply step penetrate into the front surface of the resist film R. In this way, very fine holes and cracks are formed in the resist film R. Subsequently, when the organic solvent is supplied to the resist film R, this organic solvent penetrates into the fine holes and cracks since having the low surface tension. In this way, the resist film R is pushed and expanded from inside by the organic solvent and the fine holes and cracks are further expanded. As a result, the resist film R is destroyed and removed from the front surface Sa of the substrate S. In this way, a chemical action, i.e. deterioration by the active species and a physical action, i.e. expansion of the holes and cracks by the organic solvent having the low surface tension are coupled, and the removal of the resist film R is accomplished.

Note that, according to an experiment of an inventor of the present application, the following result has been obtained. In this experiment, active species activated by a plasma were irradiated to the resist film R of the substrate S by a commercially available pen-type atmospheric pressure plasma device. Note that a so-called high dose layer to which ions have been implanted at a high concentration was formed on the surface layer of the resist film R. A plasma was generated by plasmatizing an argon gas, and the generation of active species including hydroxyl radicals was confirmed based on an emission color from the plasma. When the resist film R, to which the active species activated by the plasma were irradiated in this way, was washed by ethanol for about 10 min, the resist film R was removed from the substrate S in a range subjected to the irradiation of the active species. Note that the resist film R could be removed by ethanol washing without depending on an elapsed time from the irradiation of the active species to the ethanol washing, and the resist film R could be suitably removed, for example, even after the elapse of three days.

Further, in the above embodiment, the active species including the hydroxyl radicals are supplied to the resist film R. These radicals can precisely deteriorate the resist film R. Thus, the subsequent removal of the resist film R by the supply of the organic solvent can be efficiently performed.

Further, the plasma generator 12 is arranged to face the front surface of the substrate S, and the radicals produced by the plasma P generated by the plasma generator 12 are supplied to the resist film R. In such a configuration, the radicals can be precisely supplied to the resist film R from the plasma generator 12 arranged to face the front surface Sa of the substrate S.

Here, the active species including the hydroxyl radicals need to travel a distance from the plasma P for producing the active species to the front surface of the resist film R within the lives of thereof. What needs to be noted here is that an arc discharge occurs between electrodes and a substrate to damage the substrate if a distance between the electrodes for generating the plasma P and the substrate is too short. Accordingly, the electrodes and the substrate need to be sufficiently spaced apart so that an arc discharge does not occur. In the case of the embodiment shown in FIG. 3, the plasma P is formed between the electrodes 122 of FIG. 3 and the resist film R. The plasma P can reach a position about several mm below the electrodes 122. By bringing a lower side of the plasma P into contact with the front surface of the resist film R, hydroxyl radicals having a half-life of about 30 μs can be supplied to the front surface of the resist R.

Further, according to the above embodiment, the hardened layer of the resist film R hardened by ion implantation can be effectively removed.

Note that the invention is not limited to the embodiment described above and various changes other than the aforementioned ones can be made without departing from the gist of the invention. For example, the organic solvent having the low surface tension is not limited to the above example and the rinsing liquid is also not limited to the above example.

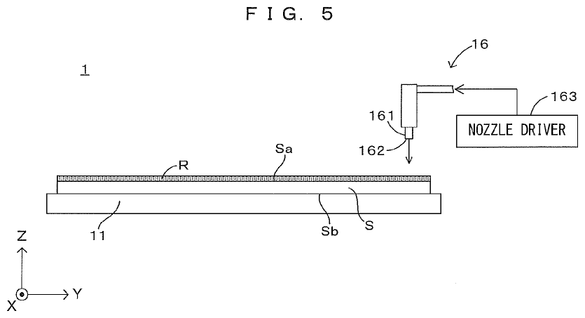

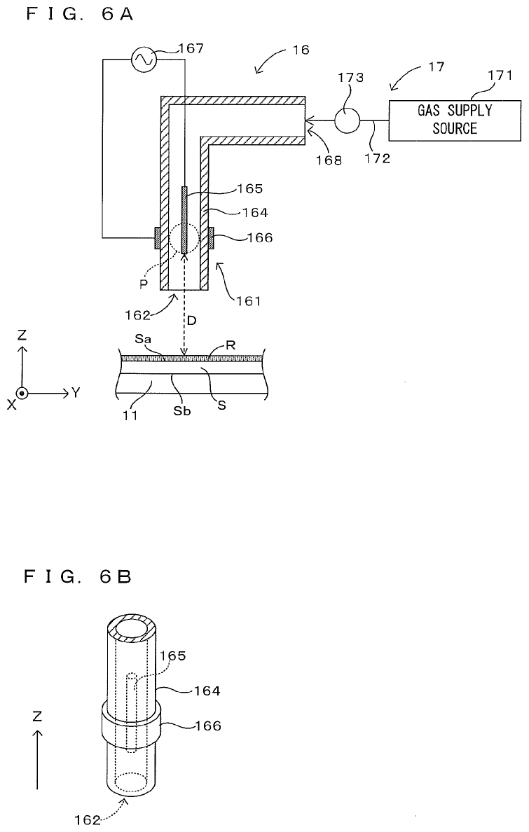

Further, the specific configuration of the plasma processing apparatus used in the plasma processing of Step S102 is not limited to the above example and may be a configuration shown in FIGS. 5, 6A and 6B. FIG. 5 is a diagram schematically showing a modification of the plasma processing apparatus, FIG. 6A is a partial sectional view schematically showing a plasma generator equipped in the plasma processing apparatus of FIG. 5, and FIG. 6B is a partial perspective view schematically showing the plasma generator equipped in the plasma processing apparatus of FIG. 5. The plasma processing apparatus 1 according to the modification includes a holding table 11 and the holding table 11 holds a substrate S as in the above embodiment.

In this modification, a plasma generator 16 is equipped. The plasma generator 16 includes a nozzle 161 for spraying a plasma P generated under an atmospheric pressure by an air flow. This nozzle 161 has a circular discharge port 162. This discharge port 162 faces a resist film R formed on a front surface Sa of the substrate S held on the holding table 11 from above, and the plasma P is sprayed toward the resist film R from the discharge port 162.

Specifically, as shown in FIGS. 6A and 6B, the nozzle 161 includes a pipe 164 and a pair of electrodes 165, 166 provided in and on the pipe 164. An opening facing downward of the pipe 164 is equivalent to the above discharge port 162. The electrode 165 has a bar shape extending in the Z direction and is arranged in the pipe 164, and the electrode 166 has a ring shape open in the Z direction and is arranged outside the pipe 164 to surround the pipe 164. Further, the plasma generator 16 includes an alternating-current power source 167 connected to the electrodes 165, 166, and the alternating-current power source 167 applies an alternating-current voltage between the electrodes 165 and 166. As a result, the plasma P is generated between the electrodes 165 and 166, in other words, around the electrode 165, in the pipe 164 of the nozzle 161.

Further, the plasma generator 16 includes a gas supply mechanism 17 which supplies a gas to the nozzle 161. The gas supply mechanism 17 includes a gas supply source 171 and a gas pipe 172. This gas pipe 172 connects an inflow port 168, which is an opening opposite to the discharge port 162 of the pipe 164 of the nozzle 161, and the gas supply source 171, and the gas supplied from the gas supply source 171 to the gas pipe 172 flows into the pipe 164 of the nozzle 161. Further, the gas supply mechanism 17 includes a flow regulator valve 173 provided in the gas pipe 172, and a flow rate of the gas flowing into the nozzle 161 from the gas supply source 171 is regulated by the flow regulator valve 173. In this way, the gas flowing into the nozzle 161 reaches between the electrodes 165 and 166 and is plasmatized by the alternating-current voltage by the alternating-current power source 167.

At this time, oxygen is present inside the nozzle 161. Accordingly, oxygen is activated by the plasma P, and active species including hydroxyl radicals are produced (radical production step). Then, these active species are sprayed to the resist film R by an air flow generated by the gas supply mechanism 17 of the plasma generator 16 (radical supply step).

At this time, the plasma P is generated near the electrode 165 in the nozzle 161. Accordingly, to let the hydroxyl radicals having a half-life of about 30 μs reach the front surface of the resist R, it is desirable that a gas flow velocity from the discharge port 162 is increased and a distance between the electrode 165 and the resist R is made as short as possible so that the hydroxyl radicals can travel a distance D from the electrode 165 in the nozzle 161 to the resist R within the lives thereof.

The gas flow velocity depends on the opening shape of the discharge port 162 and a gas supply flow rate by the gas supply mechanism 17. For example, it was confirmed by simulation that a gas flow velocity of 170 m/s was achieved by supplying the gas at a flow rate of 3 L/min using the nozzle 161 having the discharge port 162 with a rectangular opening having a height of 0.3 mm and a width of 1 mm. In this case, a distance reachable by a half-life of 30 μs is 30 μs×170 m/s=5.1 mm. Thus, under this apparatus condition, hydroxyl radicals can be properly supplied to the front surface of the resist R by setting a distance from the electrode 165 in the nozzle 161 to the front surface of the resist R at 5 mm or less.

Note that the electrode 165 and the substrate S need to be sufficiently spaced apart to avoid an arc discharge. According to the inventor's experiment, the substrate S and the electrode 165 need to be spaced apart by a minimum of 2 mm in the gas spray-type embodiment illustrated in FIG. 6A.

Further, a nozzle driver 163 (FIG. 5) which drives the nozzle 161 in the Y direction is provided in this modification. Accordingly, the active species activated by the plasma P can be sprayed to the entire front surface Sa of the substrate S by driving the nozzle 161 by the nozzle driver 163 while spraying the active species activated by the plasma P from the nozzle 161.

That is, according to this modification, the radicals are supplied to the resist film R by an air flow toward the front surface Sa of the substrate S in the radical supply step. In such a configuration, the radicals can be precisely supplied to the resist film R by the air flow toward the front surface Sa of the substrate S.

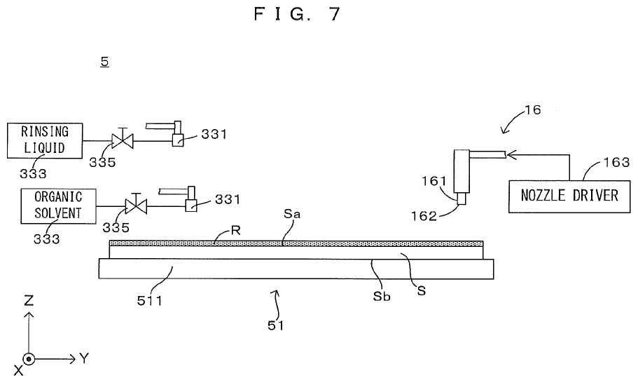

Further, as shown in FIG. 7, a substrate processing apparatus may be configured which include nozzles respectively for active species, an organic solvent and a rinsing liquid. FIG. 7 is a diagram schematically showing an example of a substrate processing apparatus according to the invention. This substrate processing apparatus 5 includes a substrate holder 51, and the substrate holder 51 horizontally holds the substrate S placed on a holding plate 511.

Further, the substrate processing apparatus 5 includes the above plasma generator 16, and the plasma generator 16 sprays active species (hydroxyl radicals) to the entire front surface Sa of the substrate S by driving the nozzle 161 by the nozzle driver 163 while discharging the active species from the discharge port 162 of the nozzle 161. Note that a distance from the electrode 165 to the front surface of the resist film R is set at 2 mm or more and 5 mm or less. Accordingly, hydroxyl radicals included in the active species can reach from the electrode 165 to the front surface of the resist film R within the lives thereof, and an arc discharge between the electrode 165 and the substrate S is avoided.

Furthermore, the substrate processing apparatus 5 includes the above processing liquid supply mechanisms 33a, 33b. The processing liquid supply mechanism 33a supplies the organic solvent to the entire front surface Sa of the substrate S by driving the nozzle 331 while discharging the organic solvent from the nozzle 331. In this way, the resist film R to which the active species were sprayed can be removed from the substrate S by the organic solvent. Further, the processing liquid supply mechanism 33a supplies the rinsing liquid to the entire front surface Sa of the substrate S by driving the nozzle 331 while discharging the rinsing liquid from the nozzle 331. In this way, a rinsing process by the rinsing liquid can be performed for the substrate S from which the resist film R has been removed by the organic solvent.

That is, according to the inventor's research, the deterioration of the front surface of the resist film R on the substrate S under an atmospheric pressure is thought to be largely affected by the action of the hydroxyl radicals.

Accordingly, in the substrate processing apparatus 5, a distance D from the electrode 165 of the nozzle 161 (active species nozzle) to the resist film R on the substrate S held by the substrate holder 51 (holder) is set at such a distance that the hydroxyl radicals included in the active species can reach the front surface of the resist film R from the electrode 165 within the lives thereof. In this way, the front surface of the resist film R can be efficiently deteriorated.

Further, a modification different from the examples shown in FIGS. 5 to 7 can be added as appropriate. For example, the plasma processing needs not be performed to substrates one by one in a single wafer manner and may be performed to a plurality of substrates at once in a batch manner.

Further, an organic solvent process needs not be performed to substrates one by one in a single wafer manner and may be performed to a plurality of substrates at once in a batch manner. The same applies also to the rinsing process.

Further, in the above embodiment of FIGS. 3 to 5, the plasma processing (Step S102) and the organic solvent process (Step S104) are performed in the separate apparatuses (plasma processing apparatus 1, processing liquid supply apparatus 3). However, functions of the respective plasma processing apparatus and processing liquid supply apparatus may be realized by one apparatus, and the plasma processing and the organic solvent process may be performed in this apparatus. The embodiment shown in FIG. 7 corresponds to an example of this.

Further, the above embodiment can be applied also to the removal of a resist film R including no hardened layer having a high dose.

As described above, various organic solvents can be assumed as the organic solvent having the low surface tension. For example, the organic solvent having the low surface tension may be ethanol, isopropyl alcohol or acetone. These organic solvents can quickly remove the resist film deteriorated by the radicals.

Further, various radicals can be assumed as the radicals. For example, radicals may be active species. Particularly, radicals may be hydroxyl radicals. These radicals can precisely deteriorate the resist film.

The substrate processing method may be configured so that the plasma is generated by a plasma generator arranged to face the front surface of the substrate in the plasma generation step, and a distance from an electrode of the plasma generator to the front surface of the resist film formed on the front surface of the substrate is shorter than a distance reachable by the radicals within the lives of the radicals and more than 0. In such a configuration, the radicals can be precisely supplied to the resist film from the plasma generator arranged to face the front surface of the substrate.

For example, the distance from the electrode of the plasma generator to the front surface of the resist film formed on the front surface of the substrate may be 2 mm or more and 5 mm or less. In this way, the radicals can be precisely supplied from the plasma generator to the resist film.

The substrate processing method may be configured so that the radicals are supplied to the resist film by an air flow toward the front surface of the substrate in the radical supply step. In such a configuration, the radicals can be precisely supplied to the resist film by the air flow toward the front surface of the substrate.

Further, the above substrate processing method can be performed in removing a resist film having ions implanted thereinto. That is, the above substrate processing method can effectively remove a hardened layer of the resist film hardened by ion implantation.

For example, the distance from the electrode inside the active species nozzle to the front surface of the resist film on the substrate held by the holder may be 2 mm or more and 5 mm or less.

This invention can be applied to techniques in general for removing a resist film R from a substrate S.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A substrate processing method, comprising:
a plasma generation step of generating a plasma under an atmospheric pressure;
a radical production step of producing radicals by the plasma generated in the plasma generation step;
a radical supply step of supplying the radicals to a resist film formed on a front surface of a substrate and deteriorating the vicinity of a front surface of the resist film while keeping the resist film in contact with the front surface of the substrate;
a resist removal step of removing the resist film from the front surface of the substrate by supplying an organic solvent having a low surface tension to the resist film on the front surface of the substrate after the radical supply step; and
a rinsing step of supplying a rinsing liquid to the front surface of the substrate after the resist removal step.

2. The substrate processing method according to claim 1, wherein the organic solvent having the low surface tension is ethanol, isopropyl alcohol or acetone.

3. The substrate processing method according to claim 1, wherein the radicals are active species.

4. The substrate processing method according to claim 3, wherein the radicals are hydroxyl radicals.

5. The substrate processing method according to claim 1, wherein:
the plasma is generated by a plasma generator arranged to face the front surface of the substrate in the plasma generation step, and
a distance from an electrode of the plasma generator to the front surface of the resist film formed on the front surface of the substrate is shorter than a distance reachable by the radicals within the lives of the radicals and more than 0.

6. The substrate processing method according to claims 5, wherein:
the distance from the electrode of the plasma generator to the front surface of the resist film formed on the front surface of the substrate is 2 mm or more and 5 mm or less.

7. The substrate processing method according to claim 1, wherein the radicals are supplied to the resist film by an air flow toward the front surface of the substrate in the radical supply step.

8. The substrate processing method according to claim 1, wherein ions are implanted into the resist film.

9. A substrate processing apparatus which removes a resist film on a substrate, comprising:
a holder which horizontally holds the substrate under an atmospheric pressure;
a plasma generator which includes an active species nozzle and an electrode arranged inside the active species nozzle and supplies active species activated by a plasma generated by applying a voltage to the electrode by the active species nozzle; and
an organic solvent nozzle which supplies an organic solvent having a low surface tension,
wherein a distance from the electrode inside the active species nozzle to a front surface of the resist film on the substrate held by the holder is set at such a distance that hydroxyl radicals included in the active species reach the front surface of the resist film from the electrode within the lives of the hydroxyl radicals.

10. The substrate processing apparatus according to claim 9, wherein the distance from the electrode inside the active species nozzle to the front surface of the resist film on the substrate held by the holder is 2 mm or more and 5 mm or less.
